(19) United States
(12) Patent Application Publication
(10) Pub. No.: US 2010/0020371 A1
(43) Pub. Date: Jan. 28, 2010

(54) DIGITAL PHOTO ALBUM, DISPLAY METHOD THEREOF AND CONTROLLER USING THE DISPLAY METHOD

(75) Inventors: Chin-Lin Sun, Hsinchu County (TW); Yun-Hsi Tseng, Tainan City (TW); Chih-Kai Chi, Tainan City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: FLEXMEDIA ELECTRONICS CORP., Hsinchu County (TW)

(21) Appl. No.: 12/275,229

(22) Filed: Nov. 21, 2008

(30) Foreign Application Priority Data
Jul. 24, 2008 (TW) 97128139

(51) Int. Cl. G03F 3/10

(52) U.S. Cl. 358/527

(57) ABSTRACT

Digital photo albums, display methods thereof and controllers using the display methods are provided by the present invention so that a user can have a page-turning effect during switching digital photos. The first display method with the page-turning effect includes generating a plurality of digital photos with an arbitrary quadrilateral, and sequentially displaying the present digital photo, the plurality of digital photos with an arbitrary quadrilateral and the next digital photo. The second display method with the page-turning effect includes respectively dividing the digital photo and the next digital photo into a plurality of image data blocks, sequentially generating a plurality of intermediate digital photos according to the image data blocks of the present digital photo and the next digital photo and sequentially displaying the present digital photo, the intermediate digital photos and the next digital photo on a screen.

### CROSS-REFERENCE TO RELATED APPLICATION

This application claims the priority benefit of Taiwan application serial no. 97128139, filed on Jul. 24, 2008. The entirety of the above-mentioned patent application is hereby incorporated by reference herein and made a part of specification.

### BACKGROUND OF THE INVENTION

1. Field of the Invention

The present invention generally relates to a digital photo album, a display method thereof and a controller using the display method, and more particularly, to a digital photo album, a display method thereof and a controller using the display method with the page-turning effect.

2. Description of Related Art

In recent years, the traditional optical camera with a film as recording media has been gradually replaced by the digital camera. The major feature of a digital camera rests in that the taken photos are no more recorded on a film; instead, the taken photos are recorded as digital images, so that they can directly viewed through a computer without being developed and printed. It is estimated, at least twenty billions photos every year are taken by digital cameras, wherein nearly 60% of the photos are not developed and printed but directly viewed on electronic display panels. For consumers to more conveniently browse and view digital photos, a new product, digital photo frame, was emerged on the market.

The primary function of a digital photo frame is to play digital images on an independent and special digital photo display screen, wherein the digital images were played on a computer or a TV set before. The most of digital photo frames today are equipped with built-in slots for accommodating memory cards where the digital photos to be played are accessed. To view the photos stored in the memory card, a user needs to insert the memory card from a digital camera into the slot of the digital photo frame and press down the buttons thereof, such as the buttons for the last page, the next page and the like. Indeed, such a job with a digital photo frame is much easier than before.

FIG. 1 is a diagram showing a momentary action to turn page on a traditional photo album. Referring to FIG. 1, a digital photo album 10 includes pages Page_1-Page_3, wherein the page Page_1 contains photos Pic_1 and Pic_2, the page Page_2 contains photos Pic_3 and Pic_4 and the page Page_3 contains photos Pic_5 and Pic_6. As a user turns page from the page Page_1 to the page Page_2 (i.e., the page Page_2 is opening and the page Page_1 is being covered by Page_2), parts of the photos Pic_1 and Pic_2 are shaded by the page Page_2 itself, as shown by FIG. 1. Moreover, the photos Pic_3 and Pic_4 viewed by the user have different shape look from that of the photos Pic_5 and Pic_6, where the photos Pic_5 and Pic_6 have rectangle shape, but the photos Pic_3 and Pic_4 at the moment do not (P.S. a rectangle includes a square; but a square is counted as a special case of a rectangle only).

It is obvious that with a digital photo frame a user is allowed to manipulate the above-mentioned buttons to view and switch photos and is unable to simultaneously see two or three pages during turning page with a traditional photo album and to see the photo shape the same as the photos Pic_3 and Pic_4 shown by FIG. 1 during turning pages. In short, a user with a digital photo frame can not have the page-turning effect the same as the traditional photo album.

### SUMMARY OF THE INVENTION

Accordingly, the present invention is directed to several digital photo albums, display methods thereof and controllers using the display methods, with which a user is able to switch digital photos with a virtual feeling of the traditional page-turning effect.

The principle aspect of the present invention provides a display method for a digital photo album. The display method includes following steps: (a) receiving the image data of all the points of a first digital photo; (b) displaying the first digital photo, wherein the first digital photo has a rectangle shape; (c) converting the first digital photo into a second digital photo with an arbitrary quadrilateral shape according to a linear transformation formula; (d) displaying the second digital photo.

According to an exemplary example of the present invention, a controller used in a digital photo album is provided, wherein the controller includes a memory circuit and a central processing unit (CPU) both coupled to each other. The memory circuit has a plurality of machine commands that can be executed by the central processing unit to execute a plurality of display steps, and the display steps comprise:: (a) receiving the image data of all the points of the first digital photo from the storage device; (b) displaying the first digital photo on the display device, wherein the first digital photo has a rectangle shape; (c) converting the first digital photo into a second digital photo with an arbitrary quadrilateral shape according to the linear transformation formula; (d) displaying the second digital photo on the display device.

According to an exemplary example of the present invention, a digital photo album is provided. The digital photo album includes a controller, a display device and a storage device, wherein the controller includes a memory circuit and a CPU both coupled to each other. The display device and the storage device are coupled to the controller. The memory circuit have a plurality of machine commands that can be executed by the central processing unit to execute a plurality of display steps, the display steps comprise: (a) receiving the image data of all the points of the first digital photo from the storage device; (b) displaying the first digital photo on the display device, wherein the first digital photo has a rectangle shape; (c) converting the first digital photo into a second digital photo with an arbitrary quadrilateral shape according to the linear transformation formula; (d) displaying the second digital photo on the display device.

According to an exemplary example of the present invention, a display method for a digital photo album is provided. The display method includes following steps: (a) receiving the image data of all the points of the first digital photo; (b) displaying the first digital photo; (c) receiving the image data of all the points of a third digital photo, wherein the third digital photo is just the next digital photo of the first digital photo; (d) respectively dividing the first digital photo and third digital photo into r image data blocks, wherein r is an integer and each image data block contains a plurality of image data; (e) generating a second digital photo, wherein the second digital photo contains r image data blocks which are generated according to the r image data blocks in the first digital photo and the r image data blocks in the third digital photo; (f) displaying the second digital photo.

According to an exemplary example of the present invention, a controller used in a digital photo album is provided, wherein the controller includes a memory circuit and a central processing unit (CPU) both coupled to each other. The memory circuit has a plurality of machine commands that can be executed by the central processing unit to execute a plurality of display steps, and the display steps comprise: (a) receiving the image data of all the points of the first digital photo from a storage device; (b) displaying the first digital photo on the display device; (c) receiving the image data of all the points of the third digital photo from the storage device, wherein the third digital photo is just the next digital photo of the first digital photo; (d) respectively dividing the first digital photo and third digital photo into r image data blocks, wherein r is an integer and each image data block contains a plurality of image data; (e) generating a second digital photo, wherein the second digital photo contains r image data blocks which are generated according to the r image data blocks of the first digital photo and the r image data blocks of the third digital photo; (f) displaying the second digital photo on the display device.

According to an exemplary example of the present invention, a digital photo album is provided. The digital photo album includes a controller, a display device and a storage device, wherein the controller includes a memory circuit and a CPU both coupled to each other. The display device and the storage device are coupled to the controller. The memory circuit have a plurality of machine commands that can be executed by the central processing unit to execute a plurality of display steps, the display steps comprise: (a) receiving the image data of all the points of the first digital photo from the storage device; (b) displaying the first digital photo on the display device; (c) receiving the image data of all the points of the third digital photo from the storage device, wherein the third digital photo is just the next digital photo of the first digital photo; (d) respectively dividing the first digital photo and third digital photo into r image data blocks, wherein r is an integer and each image data block contains a plurality of image data; (e) generating a second digital photo, wherein the second digital photo contains r image data blocks which are generated according to the r image data blocks of the first digital photo and the r image data blocks of the third digital photo; (f) displaying the second digital photo on the display device.

In summary, the present invention provides the digital photo album, the display method thereof and the controller using the display method, which are featured with the page-turning effect to make a viewer with the invented digital photo album have a virtual experience which is the same as that of the traditional album.

### BRIEF DESCRIPTION OF THE DRAWINGS

The accompanying drawings are included to provide a further understanding of the invention, and are incorporated in and constitute a part of this specification. The drawings illustrate exemplary examples of the invention and, together with the description, serve to explain the principles of the invention.

FIG. 1 is a diagram showing a momentary action to turn page on a traditional photo album.

FIGS. 2A-2D are diagrams illustrating a display method of a digital photo album provided by an exemplary example of the present invention.

FIG. 3 is a diagram showing a method for converting the shape of a digital photo according to an exemplary example of the present invention.

FIG. 4 is a flowchart of a display method provided by an exemplary example of the present invention, wherein the display method has the page-turning effect.

FIGS. 5A-5D are diagrams illustrating the steps of a display method provided by an exemplary example of the present invention.

FIG. 6 is a diagram showing the evolutions of a plurality of image data blocks and the image data thereof in a plurality of digital photos during performing the display method shown by FIGS. 5A-5D.

FIG. 7 is a diagram showing how the image data 2_new of the second image data block in the digital photo 61 is generated from the image data 1_old and 2_old of the first and second image data blocks in the digital photo 60.

FIG. 8 is a flowchart of a display method provided by another exemplary example of the present invention, wherein the display method has the page-turning effect.

FIG. 9 is a circuit diagram of a digital photo album and the controller thereof provided by an exemplary example of the present invention, wherein the digital photo album has the page-turning effect.

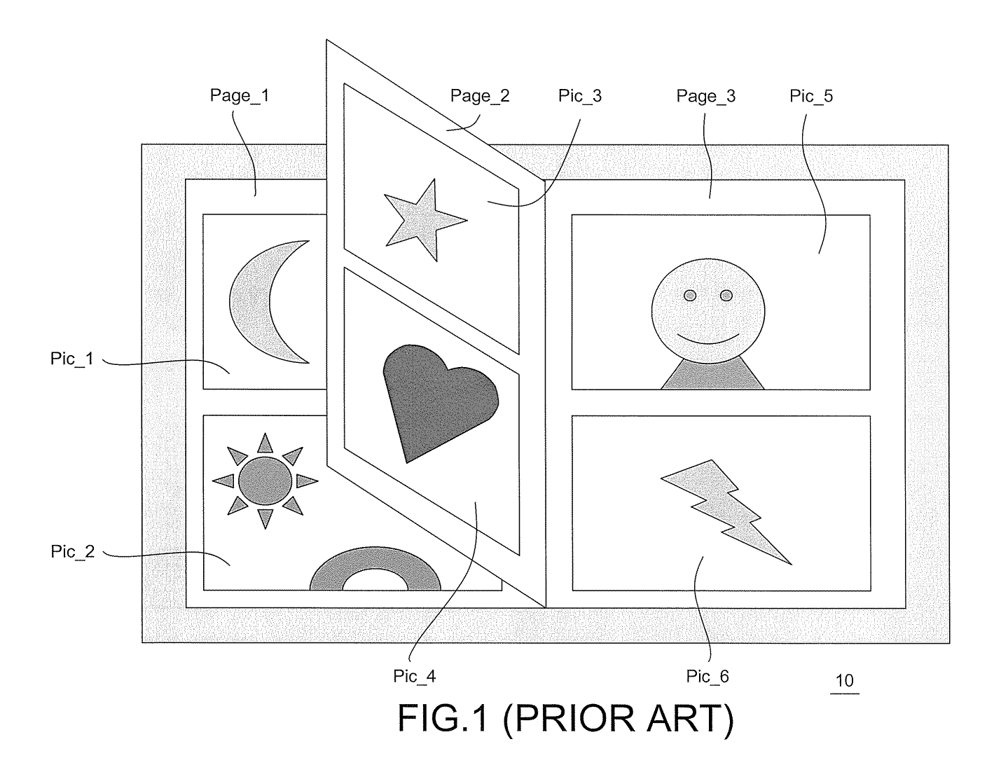

### DESCRIPTION OF THE EXEMPLARY EMBODIMENTS

Reference will now be made in detail to the present preferred exemplary examples of the invention, examples of which are illustrated in the accompanying drawings. Wherever possible, the same reference numbers are used in the drawings and the description to refer to the same or like parts.

The present invention in provides several digital photo albums, several display methods and controllers using the display methods so that the user viewing digital photos with the digital device is able to have a virtual page-turning effect which is the same as that of a traditional photo album.

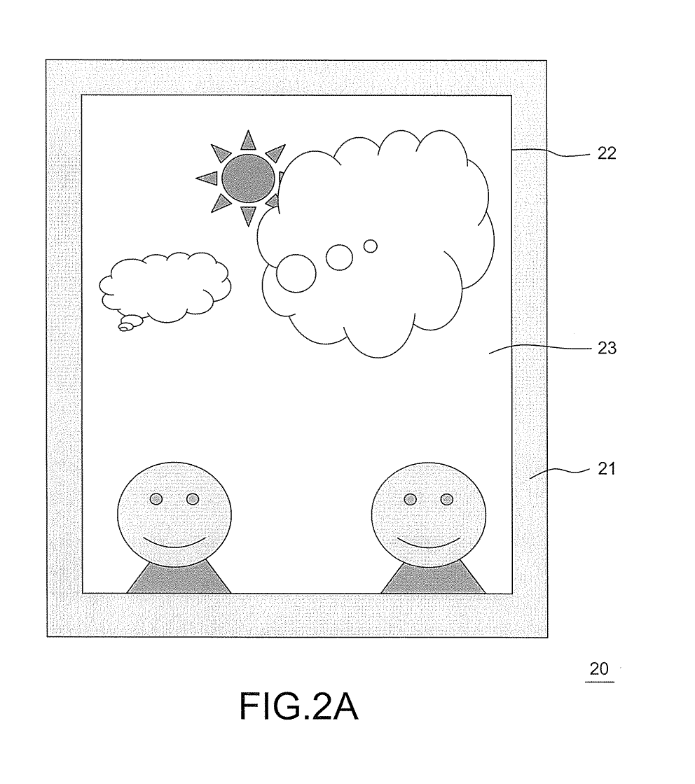

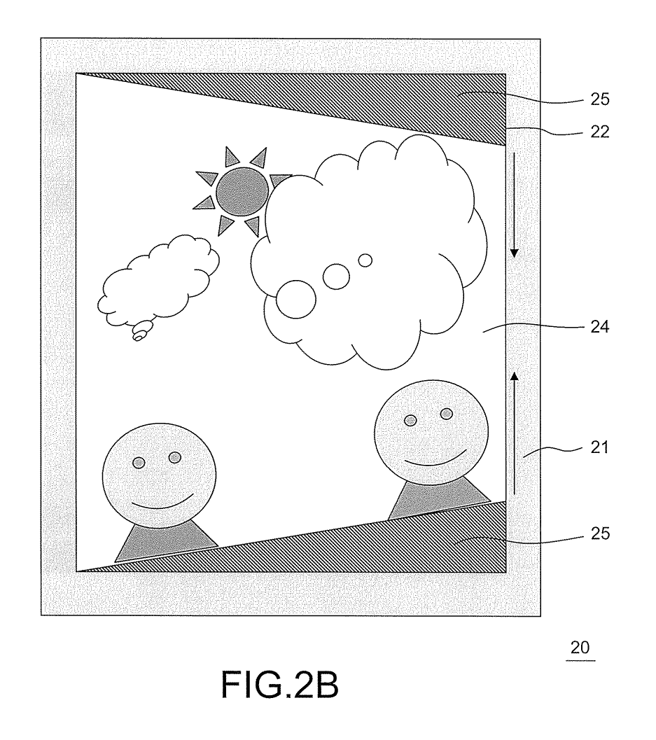

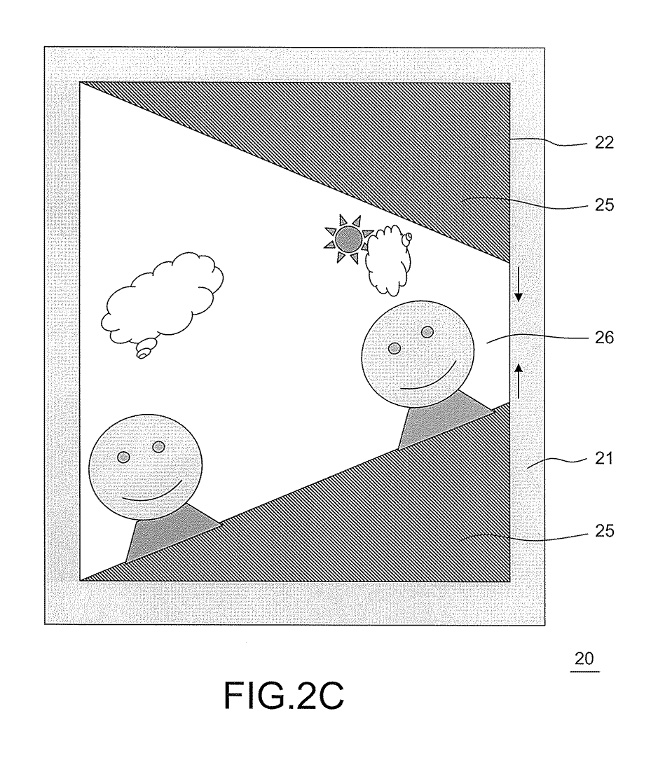

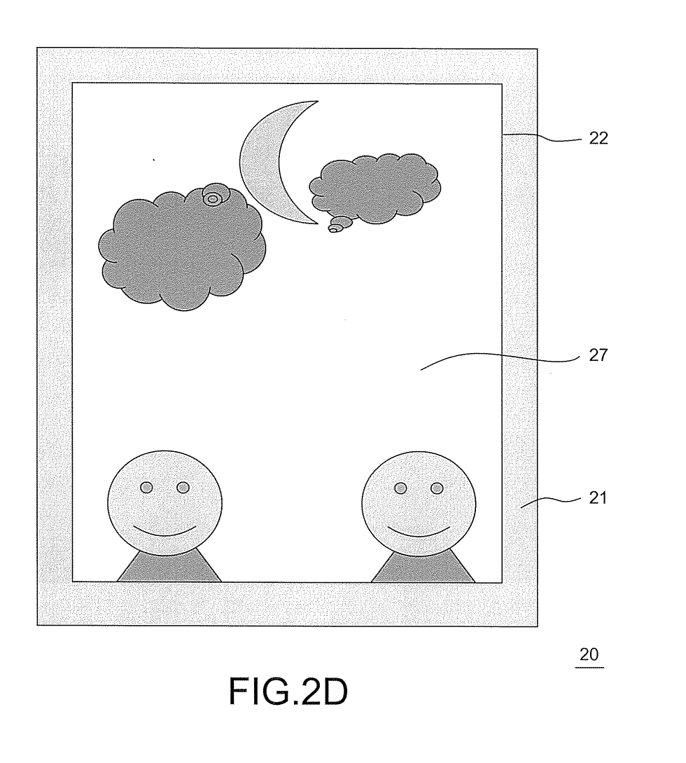

The first display method with the page-turning effect provided by an exemplary example of the present invention is depicted as follows. FIGS. 2A-2D are diagrams illustrating a display method of a digital photo album provided by an exemplary example of the present invention. Referring to FIGS. 2A-2D, a digital photo album 20 has a album body 21 and a screen 22 disposed on the album body 21, wherein the album body 21 has a circuit therein for processing the image data of digital photos to display them on the screen 22.

First referring to FIG. 2A, the digital photo album 20 displays a digital photo 23 on the screen 22 according to the image data of the digital photo 23. Next referring to FIG. 2B, the circuit of the digital photo album 20 converts the digital photo 23 shown by FIG. 2A into a digital photo 24, wherein the shape of the digital photo 23 is changed from a rectangle to a trapezoid, which is the shape of the converted digital photo 24 displayed on the screen 22. The background image layer 25 of the screen, as shown in FIG. 2B, can be the next digital photo 27 (shown in FIG. 2D) of the digital photo 23 or other background patterns, and the present invention does not limit the form and the type of the background image layer 25.

Then referring to FIG. 2C, the circuit of the digital photo album 20 converts the digital photo 23 in FIG. 2A into a digital photo 26 and displays the digital photo 26 on the screen 22. After that referring to FIG. 2D, the digital photo album 20 displays the next digital photo 27 of the digital photo 23 on the screen 22.

FIGS. 2A-2D illustrate the page-turning course and the effect thereof provided by the exemplary example; in fact, FIGS. 2A-2D are continuously displayed on the screen 22, where along with turning pages from FIG. 2A to FIG. 2D, 15 digital photos are continuously displayed in a flash, for example, in 0.5 sec. In other words, the circuit of the digital photo album 20 can continuously convert the digital photo 23 into 13 digital photos with a trapezoid shape and sequentially display the 15 digital photos on the screen 22 of the digital photo album 20 in just 0.5 sec. Note that the digital photo album 20 must display the digital photo 23 first and the digital photo 28 finally; hence, only 13 digital photos with a trapezoid shape are necessarily converted from the digital photo 23 and displayed on the screen 22.

In addition, among the four vertexes of each of the above-mentioned 13 digital photos with a trapezoid shape, there are two vertexes would be moving in the two opposite directions, as shown by the two arrows in FIGS. 2B and 2C during a page-turning action. Also, note that in the exemplary example, although a digital photo is converted into several digital photos with the trapezoid shapes for continuously displaying to reach the page-turning effect, but the present invention does not limit the shape-converting from a rectangle into a trapezoid and also does not limit the page-turning speed, for example, displaying 15 digital photos per 0.5 sec. In fact, the present invention allows converting a rectangle into an arbitrary quadrilateral, and the required time, number of the displayed digital photos and number of the digital photos to be converted during turning pages are varied with the application practice.

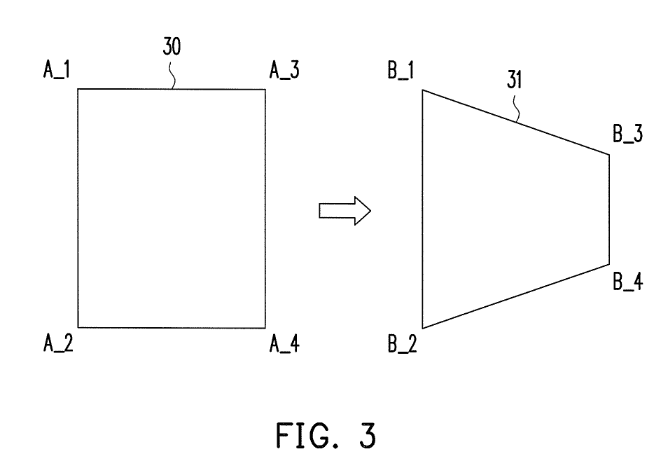

FIG. 3 is a diagram showing a method for converting the shape of a digital photo according to an exemplary example of the present invention. The shape of the above-mentioned converted digital photo is further explained. Referring to FIG. 3, in order to convert a digital photo 30 with a rectangle shape into a digital photo 31 with a trapezoid shape, a point-to-point mapping between the digital photos 30 and 31 is used, followed by copying the pixel values of a plurality of points in the digital photo 30 onto the corresponding points in the digital photo 31, wherein the pixel values are represented by the corresponding image data. For example, the four vertexes A_1-A_4 in the digital photo 30 are respectively mapped onto the four vertexes B_1-B_4 in the digital photo 31, and the pixel values (represented by image data) of the four vertexes B_1-B_4 in the digital photo 31 would be equal to those of the four vertexes A_1-A_4 in the digital photo 30.

The mapping between the above-mentioned two digital photos can be expressed by a linear transformation formula. Note that the following depiction is suitable for not only the above-mentioned point-to-point transformation from a rectangle to a trapezoid, but also the point-to-point transformation from a rectangle to an arbitrary quadrilateral. A two-dimensional point-to-point transformation from a rectangle to an arbitrary quadrilateral on a plane can be expressed by the following linear transformation formulas:

a=(Ax+By+C)/(Gx+Hy+1)

b=(Dx+Ey+F)/(Gx+Hy+1)

, wherein A-H represent transformation coefficients, (a, b) represent a pair of position coordinates of a point of a transformed arbitrary quadrilateral and the point (a, b) is corresponding to the point (x, y) of the rectangle. The above-mentioned formulas can be re-organized into the follow ones:

a=Ax+By+C−axG−ayH

b=Dx+Ey+F−bxG−byH

If the position coordinates of four points in the rectangle and the position coordinates of the corresponding four points in the arbitrary quadrilateral are given, the transformation coefficients A-H can be solved. Thus, replacing (x, y) and (a, b) in the above-mentioned formulas by the position coordinates of the four vertexes A_1-A_4 in the digital photo 30, (x₁,y₁), (x₂,y₂), (x₃,y₃) and (x₄,y₄), and the position coordinates of the four vertexes B_1-B_4 in the digital photo 31, (a₁,b₁), (a₂,b₂), (a₃,b₃) and (a₄,b₄), the above-mentioned formulas can be expressed in a matrix:

$$[ \begin{matrix}{x}_{1} & {y}_{1} & 1 & 0 & 0 & 0 & - {a}_{1} * {x}_{1} & - {a}_{1} * {y}_{1} \\ {x}_{2} & {y}_{2} & 1 & 0 & 0 & 0 & - {a}_{2} * {x}_{2} & - {a}_{2} * {y}_{2} \\ {x}_{3} & {y}_{3} & 1 & 0 & 0 & 0 & - {a}_{3} * {x}_{3} & - {a}_{3} * {y}_{3} \\ {x}_{4} & {y}_{4} & 1 & 0 & 0 & 0 & - {a}_{4} * {x}_{4} & - {a}_{4} * {y}_{4} \\ 0 & 0 & 0 & {x}_{1} & {y}_{1} & 1 & - {b}_{1} * {x}_{1} & - {b}_{1} * {y}_{1} \\ 0 & 0 & 0 & {x}_{2} & {y}_{2} & 1 & - {b}_{2} * {x}_{2} & - {b}_{2} * {y}_{2} \\ 0 & 0 & 0 & {x}_{3} & {y}_{3} & 1 & - {b}_{3} * {x}_{3} & - {b}_{3} * {y}_{3} \\ 0 & 0 & 0 & {x}_{4} & {y}_{4} & 1 & - {b}_{4} * {x}_{4} & - {b}_{4} * {y}_{4}\end{matrix} ] * [ \begin{matrix}A \\ B \\ C \\ D \\ E \\ F \\ G \\ H\end{matrix} ] = [ \begin{matrix}{a}_{1} \\ {a}_{2} \\ {a}_{3} \\ {a}_{4} \\ {b}_{1} \\ {b}_{2} \\ {b}_{3} \\ {b}_{4}\end{matrix} ]$$

After that, the transformation coefficients A-H in the above-mentioned matrix can be obtained by using Gaussian elimination approach. Then, the position coordinates of each point in the digital photo 30 are transformed to the position coordinates of the corresponding point in the digital photo 31, and the pixel values (in YC_{b}Cᵣ color space, the pixel values may be substituted by the values of Y, C_{b} and Cᵣ) of the points (x, y) represented by the image data in the digital photo 30 are copied onto the points (a, b) in the digital photo 31. At the time, the transformation from the digital photo 30 to the digital photo 31 is completed, wherein the position coordinates (a, b) in the digital photo 31 can be calculated by the following formula:

(a,b)=(Ax+By+C−axG−ayH,Dx+Ey+F−bxG−byH)

Note that the above-mentioned transformation is not an one-to-one linear transformation, but a multiple-to-one transformation. When two or more than two points in the digital photo 30 are mapped to a same point in the digital photo 31, the pixel values (or the YC_{b}Cᵣ values) of one or more than one points in the digital photo 30 can be abandoned. Only the pixel value (or the YC_{b}Cᵣ value) of the retained point is copied onto the corresponding point in the digital photo 31. The present invention does not limit the above-mentioned treatment for multiple-to-one transformation. In other exemplary examples, when two or more than two points in the digital photo 30 are mapped to one point in the digital photo 31, the pixel values (or the YC_{b}Cᵣ values) of two or more than two points in the digital photo 30 can be averaged or weighing-averaged to get a result, followed by copying the result onto the corresponding point in the digital photo 31.

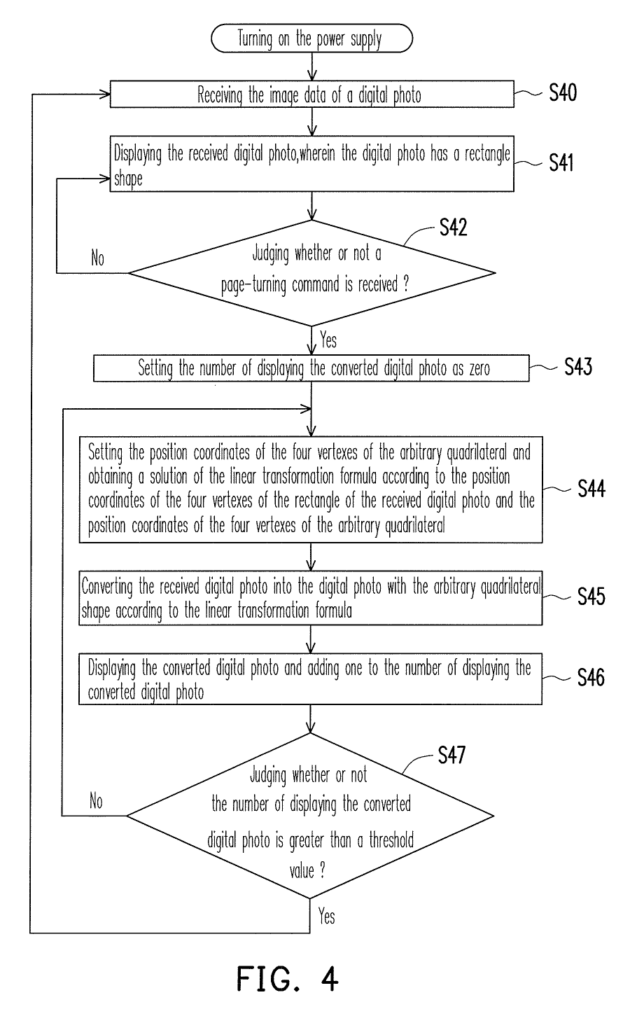

FIG. 4 is a flowchart of a display method provided by an exemplary example of the present invention, wherein the display method has the page-turning effect. Referring to FIG. 4, the display method is applicable to a digital photo album for obtaining a page-turning effect during displaying the digital photos.

First in step S40, the circuit in a digital album receives the image data of the digital photo to be displayed on a screen. Next in step S41, the received digital photo in step S40 is displayed on the screen, wherein the photo is rectangular one (as mentioned above, a rectangle includes a square; but a square is counted as a special case of a rectangle only). Then in step S42, it is judged whether or not a page-turning command is received; if the page-turning command is received, the work flow goes to step S43; otherwise, it goes to step S41 where the received digital photo would be continuously displayed on the screen of the digital photo album. In step S43 where a page-turning command is received, the number of displaying the converted digital photo is set as zero at the moment.

Then in a work flow loop comprising S44-S47, the circuit in the digital photo album generates a plurality of digital photos with arbitrary quadrilateral shapes and continuously displays the generated photos on the screen, wherein the digital photos are generated based on the digital photo received in step S40. After all the digital photos with an arbitrary quadrilateral are displayed, the work flow jumps out of the loop of steps S44-S47 and goes back to step S40, where the image data of the next digital photo to be displayed are received so as to produce a page-turning effect.

Then in step S44, the position coordinates of the four vertexes of the arbitrary quadrilateral are set and a solution of the linear transformation formula is obtained according to the position coordinates of the four vertexes of the rectangle in the received digital photo and the position coordinates of the four vertexes of the arbitrary quadrilateral, i.e., the above-mentioned transformation coefficients A-H are calculated, wherein the algorithm of the linear transformation formula is depicted hereinbefore and is omitted for simplicity.

Note that in step 44, the position coordinates of the four vertexes of the arbitrary quadrilateral are decided either by the user or by a circuit operation of the digital photo album. One of implementations thereof is shown in FIGS. 2A-2D, where the arbitrary quadrilateral is just a trapezoid and the four vertexes of the arbitrary quadrilateral are just the four vertexes of the trapezoid. Also note that, the upper side of the trapezoid resulted from each transformation is shorter than that resulted from the last transformation for producing a page-turning effect.

Then in step S45, the received digital photo is converted into a digital photo with an arbitrary quadrilateral according to the linear transformation formula, wherein the algorithm of the linear transformation formula is depicted hereinbefore and is omitted for simplicity.

Then in step S46, the converted digital photo with an arbitrary quadrilateral shape obtained in step S45 is displayed on the screen and the number of displaying the converted digital photo is added by one. Then in step S47, it is judged whether or not the number of displaying the converted digital photo is greater than a threshold value, wherein if the number of displaying the converted digital photo is greater than the threshold value, the work flow goes back to step S40 to receive the image data of a new digital photo; otherwise, it goes back to step S44 to further generate new digital photos with an arbitrary quadrilateral shape and display them on the screen until the number of displaying the converted digital photo is greater than the threshold value. In the loop comprising steps S44-S47, the threshold value is set as 12 and all the below-mentioned digital photos are sequentially displayed in 0.5*(13/15) sec (which conforms with the implementation in FIGS. 2A-2D where 15 frames are sequentially displayed per 0.5 sec). The above-mentioned displayed photos include the received digital photo in step S40 of the next circle, the received digital photo in step S40 of the present circle and the 13 digital photos with trapezoid shapes. Note that the threshold value is not limited to 12, it can be other numbers depending on different application requirements or norms.

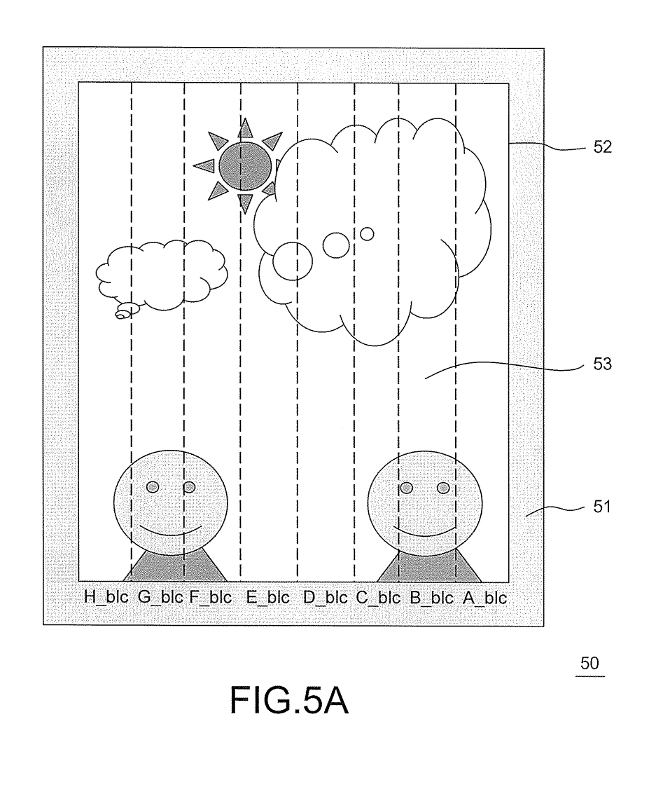

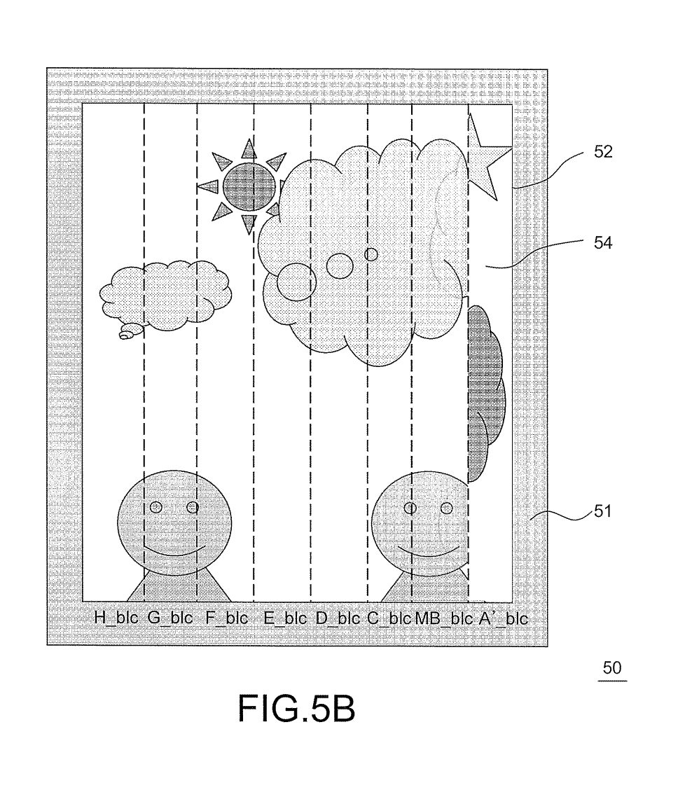

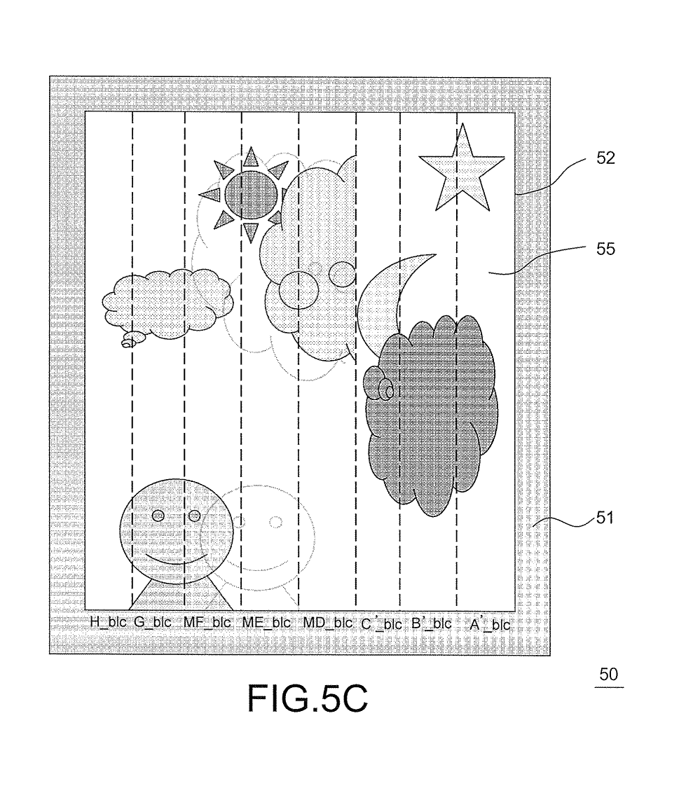

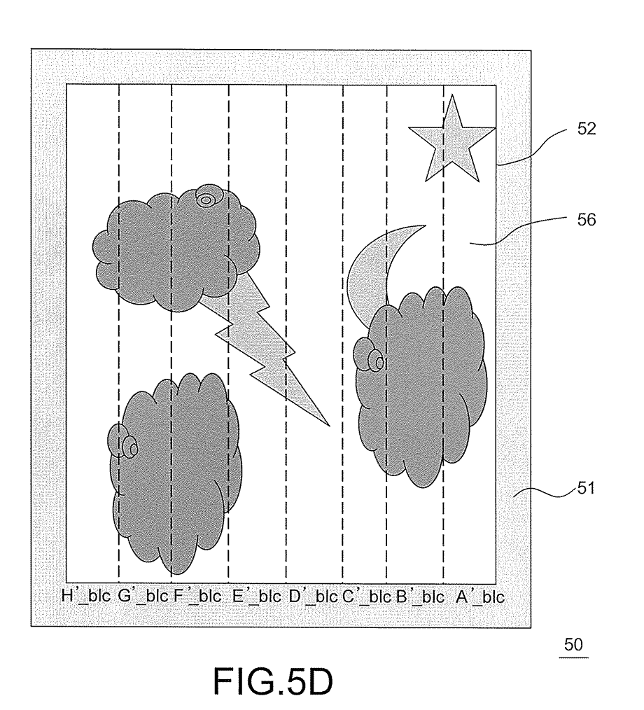

The present invention also provides another display method with page-turning effect. FIGS. 5A-5D are diagrams illustrating the steps of a display method provided by an exemplary example of the present invention. Referring to FIGS. 5A-5D, a digital photo album 50 includes an album body 51 and a screen 52 disposed on the album body 51. The album body 51 employs a circuit therein to process the image data of digital photos for displaying them on the screen 52.

First referring to FIG. 5A, the digital photo album 50 displays a digital photo 53 on the screen 52 according to the image data thereof, wherein the digital photo 53 comprises eight image data blocks A_blc, B_blc, C_blc, D_blc, E_blc, F_blc, G_blc and H_blc. and each image data block contains a plurality of image data. After the digital photo album 50 receives a page-turning command, a momentary frame is displayed on the screen 52 as shown by FIG. 5B. In FIG. 5B, a digital photo 54 is displayed which comprises eight image data blocks A′_blc, MB_blc, C_blc, D_blc, E_blc, F_blc, G_blc and H_blc, and each image data block contains a plurality of image data.

The image data of the image data blocks C_blc, D_blc, E_blc, F_blc, G_blc and H_blc of the digital photo 54 are respectively the same as the image data of the image blocks C_blc, D_blc, E_blc, F_blc, G_blc and H_blc of the digital photo 53. The image data of the image data block A′_blc of the digital photo 54 are the same as the image data of the image block A′_blc of the digital photo 56 (referring to FIG. 5D). The image data of the image data block MB_blc of the digital photo 54 is generated according to the image data of the horizontally flipped image data block A_blc in the digital photo 53 and the image data of the image data block B_blc in the digital photo 53. In this exemplary example, the image data of the image data block A_blc in the digital photo 53 is horizontally flipped, then the transparency of the horizontally flipped image data block A_blc is set as 60%, and the image data of the image data block MB_blc in the digital photo 54 is generated by adding the image data of the image data block B_blc to the horizontally flipped image data of the image data block A_blc in the digital photo 53. Note that the present invention is not limited to the above-mentioned implementation.

After displaying the frame of FIG. 5B, a momentary frame is displayed on the screen 52 as shown by FIG. 5C. In FIG. 5C, a digital photo 55 of the digital photo album 50 is displayed on the screen 52, wherein the digital photo 55 comprises eight image data blocks A′_blc, B′_blc, C′_blc, MD_blc, ME_blc, MF_blc, G_blc and H_blc, and each image data block contains a plurality of image data.

The image data of the image data blocks G_blc and H_blc of the digital photo 55 are the same as the image data of the image data blocks G_blc and H_blc of the digital photo 53, and the image data of the image data blocks A′_blc, B′_blc and C′_blc of the digital photo 55 are the same as the image data of the image data blocks A′_blc, B′_blc and C′_blc of the digital photo 56 (referring to FIG. 5D). The image data of the image data block MD_blc of the digital photo 55 is generated according to the image data of the horizontally flipped image data block C_blc in the digital photo 53 and the image data of the image data block D_blc in the digital photo 53; the image data of the image data block ME_blc of the digital photo 55 is generated according to the image data of the horizontally flipped image data block B_blc in the digital photo 53 and the image data of the image data block E_blc in the digital photo 53; the image data of the image data block MF_blc of the digital photo 55 is generated according to the image data of the horizontally flipped image data block A_blc in the digital photo 53 and the image data of the image data block F_blc in the digital photo 53.

In this exemplary example, the image data of the image data block MD_blc is generated by adding the image data of the image data block D_blc to the image data of the horizontally flipped image data block C_blc, wherein the transparency of the horizontally flipped image data block C_blc is set as 60%; the image data of the image data block ME_blc is generated by adding the image data of the image data block E_blc to the image data of the horizontally flipped image data block B_blc, wherein the transparency of the horizontally flipped image data block B_blc is set as 60%; the image data of the image data block MF_blc is generated by adding the image data of the image data block F_blc to the image data of the horizontally flipped image data block A_blc, wherein the transparency of the horizontally flipped image data block A_blc is set as 60%. In other words, if the image data blocks MD_blc, ME_blc and MF_blc are treated as a larger and merged image data block MDEF_blc, the image data blocks A′_blc, B′_blc and C′_blc are treated as a larger and merged image data block ABC_blc, and the image data blocks D′_blc, E′_blc and F′_blc are treated as a larger and merged image data block DEF_blc, then the image data of the merged image data block MDEF_blc is generated by adding the image data of the image data block DEF_blc to the image data of the horizontally flipped image data block ABC_blc, wherein the transparency of the horizontally flipped image data block ABC_blc is set as 60%. Note that the present invention is not limited to the above-mentioned implementation.

Finally in FIG. 5D, the digital photo 56 next to the digital photo 53 in the digital photo album 53 is displayed on the screen 52, wherein the digital photo 56 comprises eight image data blocks A′_blc, B′_blc, C′_blc, D′_blc, E′_blc, F′_blc, G′_blc and H′_blc, and each image data block contains a plurality of image data.

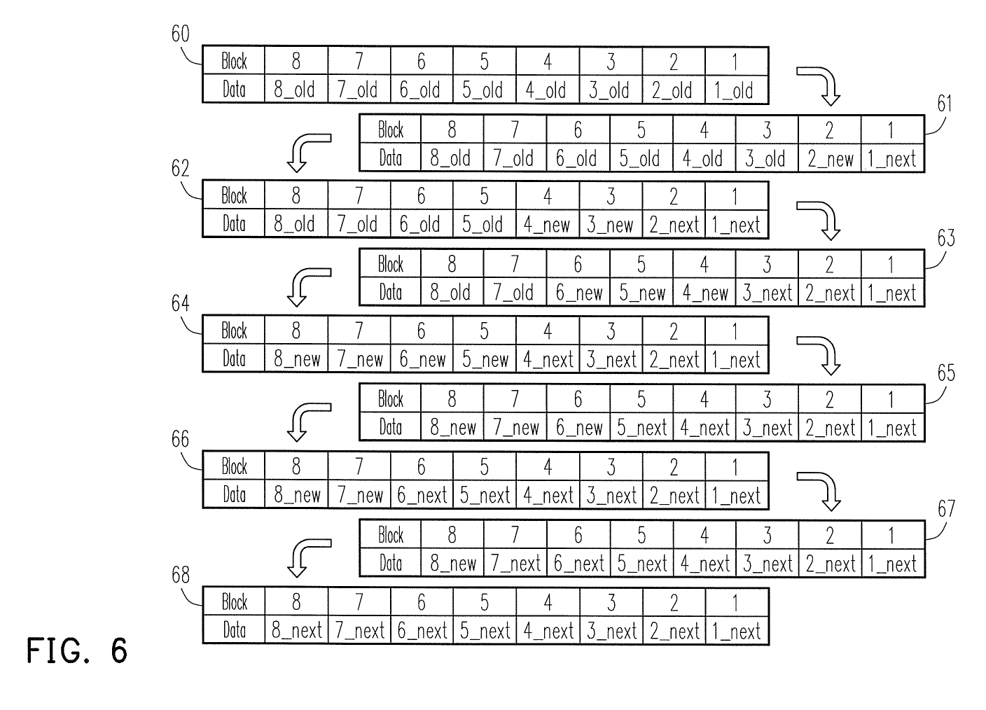

Referring to FIG. 6, FIG. 6 is a diagram showing the evolutions of a plurality of image data blocks and the image data thereof in a plurality of digital photos during performing the display method shown by FIGS. 5A-5D. In FIG. 6, it is assumed that during sequentially switching eight photos from the present digital photo 60 to the digital photo 68, seven intermediate digital photos 61-66 are sequentially and continuously displayed so as to produce a page-turning effect. In this exemplary example, it is also assumed that each of the digital photos 60-68 comprises eight image data blocks. Note that the present invention is not limited to the above-mentioned assumptions.

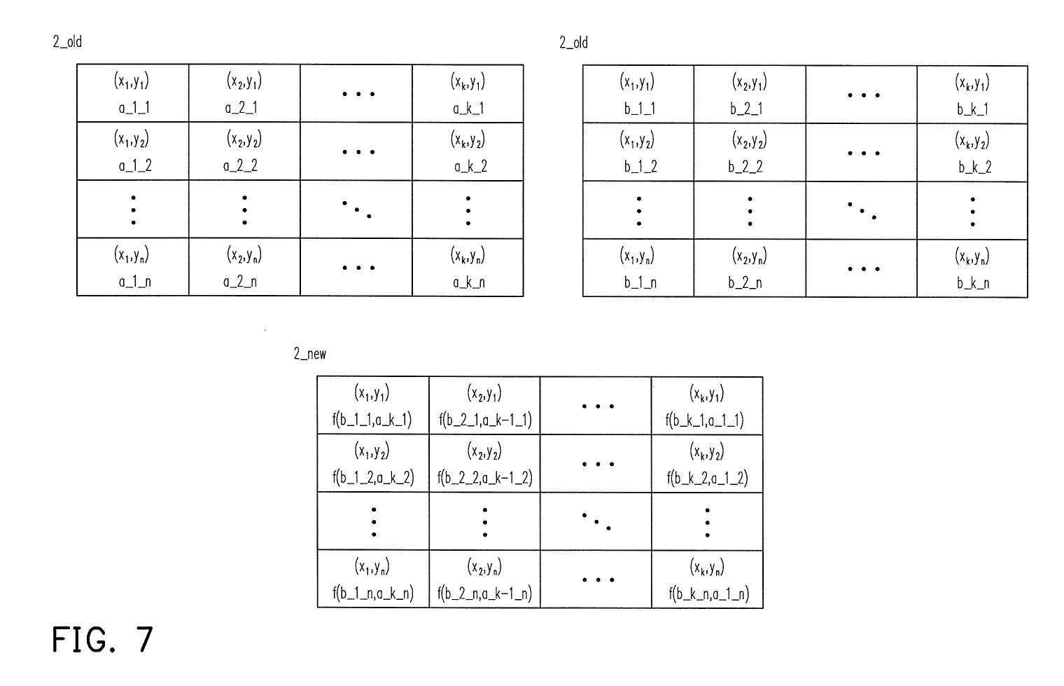

During sequentially switching eight photos from the present digital photo 60 to the digital photo 68, the intermediate digital photo 61 is generated firstly according to the image data of the image data blocks of the digital photos 60 and 68, wherein the image data of the first image data block in the intermediate digital photo 61 is the same as the image data 1_next of the first image data block in the digital photo 68, and the image data of the image data blocks from the third one to the eighth one in the intermediate digital photo 61 are the same as the image data 3_old-8_old of the image data blocks from the third one to the eighth one in the digital photo 60. Note that the image data 2_new of the second image data block in the intermediate digital photo 61 is generated according to the image data 1_old and 2_old of the first and second image data blocks in the digital photo 60, wherein the implementation to generate the image data 2_new of the second image data block in the intermediate digital photo 61 is similar to that of FIGS. 5A-5D, and the present invention also provides another implementation referring to FIG. 7.

Continuing to FIG. 6, the intermediate digital photo 62 is generated according to the image data of the image data blocks of the digital photos 60 and 68. The image data of the first and second image data blocks in the intermediate digital photo 62 are the same as the image data 1_next and 2_next of the first and second image data blocks in the digital photo 68, and the image data of the image data blocks from the fifth one to the eighth one in the intermediate digital photo 62 are the same as the image data 5_old-8_old of the image data blocks from the fifth one to the eighth one in the digital photo 60. Note that the image data 3_new of the third image data block in the intermediate digital photo 61 is generated according to the image data 2_old and 3_old of the second and third image data blocks in the digital photo 60; the image data 4_new of the fourth image data block in the intermediate digital photo 61 is generated according to the image data 1_old and 4_old of the first and fourth image data blocks in the digital photo 60.

Then, the intermediate digital photo 63 is generated according to the image data of the image data blocks of the digital photos 60 and 68, wherein the image data of the image data blocks from the first one to the third one in the intermediate digital photo 63 are the same as the image data 1_new-3_new of the image data blocks from the first one to the third one in the digital photo 68, and the image data of the seventh and eighth image data blocks in the intermediate digital photo 63 are the same as the image data 7_old and 8_old of the seventh and eighth image data blocks in the digital photo 60. Note that the image data i_new of the i-th image data block (i is an integer from 4 to 6) in the intermediate digital photo 63 is generated according to the image data i_old and (7-i)_old of the i-th and (7-i)-th image data blocks in the digital photo 60.

Then, the intermediate digital photo 64 is generated according to the image data of the image data blocks of the digital photos 60 and 68, wherein the image data of the image data blocks from the first one to the fourth one in the intermediate digital photo 64 are the same as the image data 1_next-4_next of the image data blocks from the first one to the fourth one in the digital photo 68. Note that the image data i_new of the i-th image data block (i is an integer from 5 to 8) in the intermediate digital photo 64 is generated according to the image data i_old and (9-i)_old of the i-th and (9-i)-th image data blocks in the digital photo 60.

Then, the intermediate digital photo 65 is generated according to the image data of the image data blocks of the digital photos 60 and 68, wherein the image data of the image data blocks from the first one to the fifth one in the intermediate digital photo 65 are the same as the image data 1_next-5_next of the image data blocks from the first one to the fifth one in the digital photo 68. Note that the image data i_new of the i-th image data block (i is an integer from 6 to 8) in the intermediate digital photo 65 is generated according to the image data i_old and (11-i)_old of the i-th and (11-i)-th image data blocks in the digital photo 60.

Then, the intermediate digital photo 66 is generated according to the image data of the image data blocks of the digital photos 60 and 68, wherein the image data of the image data blocks from the first one to the sixth one in the intermediate digital photo 66 are the same as the image data 1_next-6_next of the image data blocks from the first one to the sixth one in the digital photo 68. Note that the image data i_new of the i-th image data block (i is an integer 7 or 8) in the intermediate digital photo 66 is generated according to the image data i_old and (13-i)_old of the i-th and (13-i)-th image data blocks in the digital photo 60.

Then, the intermediate digital photo 67 is generated according to the image data of the image data blocks of the digital photos 60 and 68, wherein the image data of the image data blocks from the first one to the seventh one in the intermediate digital photo 67 are the same as the image data 1_next-7_next of the image data blocks from the first one to the seventh one in the digital photo 68. Note that the image data 8_new of the 8-th image data block in the intermediate digital photo 67 is generated according to the image data 7_old and 8_old of the 7-th and 8-th image data blocks in the digital photo 60.

Referring to FIG. 7, it is a diagram showing how the image data 2_new of the second image data block in the digital photo 61 is generated from the image data 1_old and 2_old of the first and second image data blocks in the digital photo 60. In FIG. 7, the image data 1_old and 2_old of the first and second image data blocks in the digital photo 60 and the image data 2_new of the second image data block in the digital photo 61 are given, which include the position coordinates of all the points and the image data values corresponding to the points. In this exemplary example, the first image data block in the digital photo 60 is horizontally flipped, then an image processing operation is performed on the image data of all the points of the horizontally flipped first image data block and the image data of all the points of the second image data block in the digital photo 60, so as to generate the image data 2_new of all the points of the second image data block in the digital photo 61.

For example, the image data of the point (xₘ,yₚ) among the image data 2_new is indicated by f(b_m_p,a_(k−m+1)_p), wherein f(•) represents an image processing operation function, b_m_p represents the image data of the point (xₘ,yₚ) among the image data 2_old, a_(k−m+1)_p represents the image data of the point (xₖ₋ₘ₊₁,yₚ) among the image data 1_old, m is an integer greater than 1 but less than k, and p is an integer greater than 1 but less than n. The above-mentioned image processing operation function f(•) can be the one for setting the transparency of the image data a_(k−m+1)_p as 60% and adding the image data b_m_p to the above-mentioned image data a_(k−m+1)_p with transparency of 60%. Note that the above-mentioned image processing operation function f(•) is one of the implementations only, which the present invention is not limited to.

In the exemplary example, it is assumed, but not limited by the present invention, that an image data block comprises the image data of the k*n points. The above-described method of how the image data 2_new of the second image data block in the digital photo 61 is generated from the image data 1_old and 2_old of the first and second image data blocks in the digital photo 60 in FIG. 7 can be applicable to generate the image data 3_new-8_new of the digital photos 62-67, and so they are omitted to describe for simplicity.

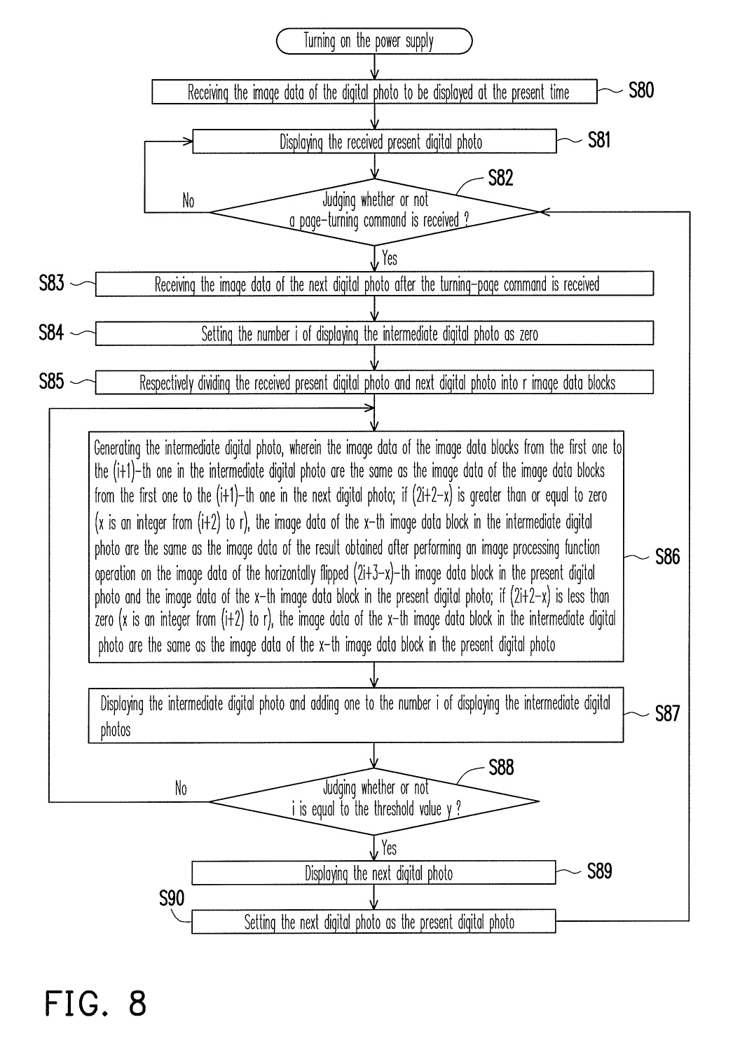

Referring to FIG. 8, it is a flowchart of a display method provided by another exemplary example of the present invention, wherein the display method is applicable to a digital photo album to provide a viewer with a page-turning effect.

First in step S80, the image data of the digital photo to be displayed at the present time is received. Next in step S81, the received present digital photo is displayed on the screen. Then in step S82, it is judged whether or not a page-turning command is received; if the page-turning command is received, the work flow goes to step S83; otherwise, it goes to step S11 where the received present digital photo would be continuously displayed.

In step S83, the image data of the next digital photo is received after the turning-page command is received; that is to say, the received digital photo is the next digital photo of the digital photo received in step S80. For example, the digital photo 53 in FIG. 5A is the present digital photo herein and the digital photo 56 in FIG. 5D is the next digital photo in the exemplary example. Then in step S84, the number i of displaying the intermediate digital photo is set as zero. Then in step S85, the received present digital photo and next digital photo are respectively divided into r image data blocks, wherein r is an integer, and as shown in FIGS. 5A-5D and 7, a digital photo is divided into eight image data blocks. Note that r=8 is just one of the implementations, which does not limit the present invention to choose other numbers.

Then in a work flow loop comprising S86-S88, a plurality of intermediate digital photos are generated based on the image data of the image data blocks of the present digital photo and the next digital photo, and the intermediate digital photos are sequentially and continuously displayed to produce a page-turning effect.

In step S86, the intermediate digital photo is generated, wherein the image data of the image data blocks from the first one to the (i+1)-th one in the intermediate digital photo are the same as the image data of the image data blocks from the first one to the (i+1)-th one in the next digital photo. If (2i+2−x) is greater than or equal to zero (x is an integer from (i+2) to r), the image data of the x-th image data block in the intermediate digital photo are same as the image data of the result obtained after performing an image processing function operation on the image data of the horizontally flipped (2i+3−x)-th image data block in the present digital photo and the image data of the x-th image data block in the present digital photo; if (2i+2−x) is less than zero (x is an integer from (i+2) to r), the image data of the x-th image data block in the intermediate digital photo are the same as the image data of the x-th image data block in the present digital photo.

In step S86, the photos similar to the digital photos 54, 55 and 61-67 in FIGS. 5B, 5C and 6 are generated, wherein the image processing function operation on the image data of the horizontally flipped (2i+3−x)-th image data block in the present digital photo and the image data of the x-th image data block in the present digital photo is similar to the above-described depiction referring to FIG. 7. Note that the type of the above-mentioned image processing function is just an example, which is not limited by the present invention.

In step S87, the intermediate digital photo is displayed in addition to adding one to the number i of displaying the intermediate digital photos. Then in step S88, it is judged whether or not i is equal to a preset threshold value y. If the number i of displaying the intermediate digital photos is equal to the preset threshold value y, the loop of steps S86-S88 is ended and the work flow goes to step S89; otherwise, the work flow goes back to step S86 until the number i of displaying the intermediate digital photos is equal to y. In the exemplary example shown by FIG. 6, r is defined as 8 and y is defined as 7. Accordingly, during turning pages from the present digital photo 60 to the next digital photo 68 as shown by FIG. 6, seven intermediate digital photos 61-67 are generated and sequentially displayed on the screen so as to provide a viewer with the page-turning effect. Note that the implementation of FIG. 6 does not limit the present invention, wherein r and y can be determined by the user according to the application requirement.

Then in step S89, the next digital photo is displayed. In step S90, the above-mentioned next digital photo is set as the present digital photo, followed by going back to step S82, so that the next digital photo herein will serves as the present digital photo next time.

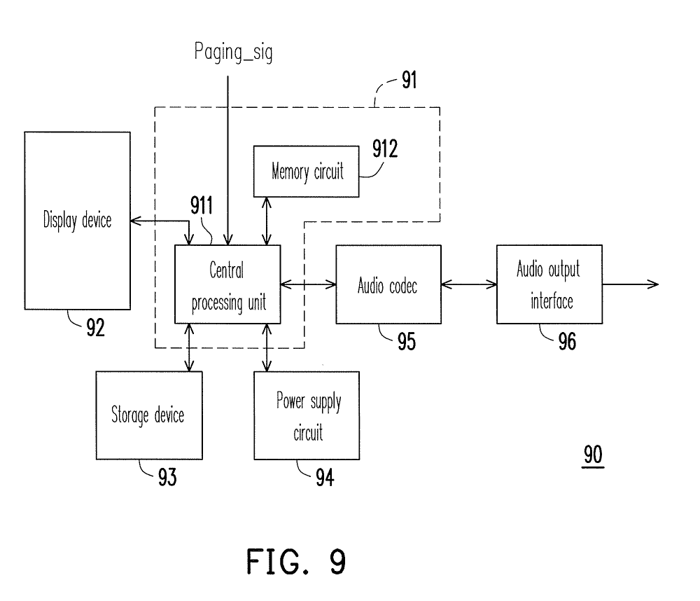

FIG. 9 is a circuit diagram of a digital photo album and the controller thereof provided by an exemplary example of the present invention, wherein the digital photo album has the page-turning effect. Referring to FIG. 9, a digital photo album 90 includes a controller 91, a display device 92, a storage device 93, a power supply circuit 94, an audio codec 95 and an audio output interface 96. The controller 91 further includes a memory circuit 912 and a CPU 911 coupled to the memory circuit 912. The display device 92, the storage device 93, the power supply circuit 94 and the audio codec 95 are coupled to the CPU 911 of the controller 91, while the audio output interface 96 is coupled to the audio codec 95.

The memory circuit 912 of the digital photo album 90 is for storing a plurality of machine commands (such as program codes generated by a program software), and the CPU 911 is for receiving the machine commands and the page-turning command paging_sig of the digital photo album 90 and for controlling the display device 92, the storage device 93, and the audio codec 95. The display device 92 is for displaying digital photos, the storage device 93 is for storing the image data of the digital photos or other data, and the power supply circuit 94 is for providing the whole digital photo album 90 with power. The audio codec 95 and the audio output interface 96 are not necessary components in the digital photo album 90; but if a user needs to listen the music during viewing digital photos, the music data stored in the storage device 93 would be accessed by the CPU 911, followed by sending the music data to the audio codec 95 for decoding. The music data after decoding then is sent to an audio player through the audio output interface 96.

The CPU 911 reads out the machine commands of the memory circuit 912 for executing the machine commands. The CPU 911 controls the storage device 93 and the display device 92 according to the machine commands and the page-turning command paging_sig and processes the digital photos uploaded from the storage device 93, so that the digital photo album 90 runs according to the display methods with a page-turning effect, which are described hereinbefore referring to FIG. 4 or 8.

In summary, the present invention provides the digital photo albums, the display methods of the digital photo albums and the controllers using the methods, so that a user is able to have the great enjoyment during playing digital photos by using the invented digital photo album with a virtual page-turning effect which is the same as the traditional photo album.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A display method for a digital photo album, comprising:
receiving the image data of all the points of a first digital photo;
displaying the first digital photo, wherein the first digital photo has a rectangle shape;
converting the first digital photo into a second digital photo with an arbitrary quadrilateral shape according to a linear transformation formula; and
displaying the second digital photo.

2. The display method according to claim 1, further comprising:
judging whether or not a page-turning command is received, wherein if the page-turning command is received, the first digital photo is converted into the second digital photo with the arbitrary quadrilateral shape according to the linear transformation formula; otherwise, the first digital photo is continuously displayed.

3. The display method according to claim 1, further comprising:
setting the position coordinates of the four vertexes of the arbitrary quadrilateral and obtaining a solution of the linear transformation formula according to the position coordinates of the four vertexes of the rectangle of the first digital photo and the position coordinates of the four vertexes of the arbitrary quadrilateral.

4. The display method according to claim 1, wherein the arbitrary quadrilateral is a trapezoid.

5. The display method according to claim 1, further comprising:
presetting a number of displaying the second digital photo as zero;
adding one to the number of displaying the second digital photo if the second digital photo is displayed;
judging whether or not the number of displaying the second digital photo is greater than a threshold value, wherein if the number of displaying the second digital photo is not greater than the threshold value, the steps of converting the first digital photo into a second digital photo with an arbitrary quadrilateral shape according to a linear transformation formula and displaying the second digital photo are conducted; if the number of displaying the second digital photo is greater than the threshold value, the image data of all the points of a third digital photo are received, wherein the third digital photo is the next digital photo of the first digital photo; and
displaying the third digital photo.

6. A controller for a digital photo album, comprising:
a central processing unit; and
a memory circuit, coupled to the central processing units, and having a plurality of machine commands that can be executed by the central processing unit to execute a plurality of display steps, the display steps comprise:
receiving the image data of all the points of a first digital photo from a storage device;
displaying the first digital photo on the display device, wherein the first digital photo has a rectangle shape;
converting the first digital photo into a second digital photo with an arbitrary quadrilateral shape according to a linear transformation formula; and
displaying the second digital photo on the display device.

7. The controller according to claim 6, wherein the steps conducted by the central processing unit according to the machine commands further comprise:
judging whether or not a page-turning command is received, wherein if the page-turning command is received, the first digital photo is converted into the second digital photo with the arbitrary quadrilateral shape according to the linear transformation formula; otherwise, the first digital photo is continuously displayed on the display device.

8. A digital photo album, comprising:
a controller;
a display device, coupled to the controller; and
a storage device, coupled to the controller;
wherein the controller comprises a memory circuit and a central processing unit, both coupled to each other, and the memory circuit have a plurality of machine commands that can be executed by the central processing unit to execute a plurality of display steps, the display steps comprise:
receiving the image data of all the points of a first digital photo from a storage device;
displaying the first digital photo on the display device, wherein the first digital photo has a rectangle shape;
converting the first digital photo into a second digital photo with an arbitrary quadrilateral shape according to the linear transformation formula; and
displaying the second digital photo on the display device.

9. The digital photo album according to claim 8, wherein the CPU further conducts a following step according to the machine commands:
judging whether or not a page-turning command is received, wherein if the page-turning command is received, the first digital photo is converted into the second digital photo with the arbitrary quadrilateral shape according to the linear transformation formula; otherwise, the first digital photo is continuously displayed on the display device.

10. A display method for a digital photo album, comprising:
receiving the image data of all the points of a first digital photo;
displaying the first digital photo;
receiving the image data of all the points of a third digital photo, wherein the third digital photo is just the next digital photo of the first digital photo;
respectively dividing the first digital photo and third digital photo into r image data blocks, wherein r is an integer and each image data block contains a plurality of image data;
generating a second digital photo, wherein the second digital photo contains r image data blocks which are generated according to the r image data blocks of the first digital photo and the r image data blocks of the third digital photo; and
displaying the second digital photo.

11. The display method according to claim 10, wherein the image data of the image data blocks from the first one to the (i+1)-th one in the second digital photo are the same as the image data of the image data blocks from the first one to the (i+1)-th one in the third digital photo; if (2i+2−x) is greater than or equal to zero, the image data of the x-th image data block in the second digital photo are the same as the image data of a result obtained after performing an image processing function operation on the image data of the horizontally flipped (2i+3−x)-th image data block in the first digital photo and the image data of the x-th image data block in the first digital photo; if (2i+2−x) is less than zero, the image data of the x-th image data block in the second digital photo are the same as the image data of the x-th image data block in the first digital photo; wherein x is an integer from (i+2) to r, and i represents a number of displaying the second digital photo.

12. The display method according to claim 11, wherein the image processing function sets the transparency of the image data of the horizontally flipped (2i+3−x)-th image data block in the first digital photo, and the image data of the x-th image data block in the second digital photo are obtained by adding the image data of the transparent horizontally flipped (2i+3−x)-th image data block in the first digital photo to the image data of the x-th image data block in the first digital photo.

13. The display method according to claim 10, further comprising:
judging whether or not a page-turning command is received, wherein if the page-turning command is received, the first digital photo and third digital photo are respectively divided into r image data blocks and then the second digital photo is generated and displayed; otherwise, the first digital photo is continuously displayed.

14. The display method according to claim 11, further comprising:
presetting the number of displaying the second digital photo as zero;
adding one to the number of displaying the second digital photo if the second digital photo is displayed; and
judging whether or not the number of displaying the second digital photo is greater than a threshold value, wherein if the number of displaying the second digital photo is not greater than the threshold value, the steps of generating the second digital photo and displaying the second digital photo are conducted; if the number of displaying the second digital photo is greater than the threshold value, the third digital photo is displayed and set as the first digital photo.

15. A controller for a digital photo album, comprising:
a central processing unit; and
a memory circuit, coupled to the central processing units, and having a plurality of machine commands that can be executed by the central processing unit to execute a plurality of display steps, the display steps comprise:
receiving the image data of all the points of a first digital photo from a storage device;
displaying the first digital photo on the display device;
receiving the image data of all the points of a third digital photo from the storage device, wherein the third digital photo is just the next digital photo of the first digital photo;
respectively dividing the first digital photo and third digital photo into r image data blocks, wherein r is an integer and each image data block contains a plurality of image data;
generating a second digital photo, wherein the second digital photo contains r image data blocks, and the r image data blocks of the second digital photo are generated according to the r image data blocks of the first digital photo and the r image data blocks of the third digital photo; and
displaying the second digital photo on the display device.

16. The controller according to claim 15, wherein the image data of the image data blocks from the first one to the (i+1)-th one in the second digital photo are the same as the image data of the image data blocks from the first one to the (i+1)-th one in the third digital photo; if (2i+2−x) is greater than or equal to zero, the image data of the x-th image data block in the second digital photo are the same as the image data of a result obtained after performing an image processing function operation on the image data of the horizontally flipped (2i+3−x)-th image data block in the first digital photo and the image data of the x-th image data block in the first digital photo; if (2i+2−x) is less than zero, the image data of the x-th image data block in the second digital photo are the same as the image data of the x-th image data block in the first digital photo; wherein x is an integer from (i+2) to r, and i represents a number of displaying the second digital photo.

17. The controller according to claim 16, wherein the image processing function sets the transparency of the image data of the horizontally flipped (2i+3−x)-th image data block in the first digital photo, and the image data of the x-th image data block in the second digital photo are obtained by adding the image data of the transparent horizontally flipped (2i+3−x)-th image data block in the first digital photo to the image data of the x-th image data block in the first digital photo.

18. The controller according to claim 15, wherein the steps conducted by the central processing unit according to the machine commands further comprise:
judging whether or not a page-turning command is received, wherein if the page-turning command is received, the first digital photo and third digital photo are respectively divided into r image data blocks and then the second digital photo is generated and displayed; otherwise, the first digital photo is continuously displayed on the display device.

19. The controller according to claim 16, wherein the steps conducted by the central processing unit according to the machine commands further comprise:
presetting the number of displaying the second digital photo as zero;
adding one to the number of displaying the second digital photo if the second digital photo is displayed; and
judging whether or not the number of displaying the second digital photo is greater than a threshold value, wherein if the number of displaying the second digital photo is not greater than the threshold value, the steps of generating the second digital photo and displaying the second digital photo on the display device are conducted; if the number of displaying the second digital photo is greater than the threshold value, the third digital photo is displayed on the display device and set as the first digital photo.

20. A digital photo album, comprising:
a controller;
a display device, coupled to the controller; and
a storage device, coupled to the controller;
wherein the controller comprises a memory circuit and a central processing unit, both coupled to each other, and the memory circuit have a plurality of machine commands that can be executed by the central processing unit to execute a plurality of display steps, the display steps comprise:
receiving the image data of all the points of a first digital photo from the storage device;
displaying the first digital photo on the display device;
receiving the image data of all the points of a third digital photo from the storage device, wherein the third digital photo is just the next digital photo of the first digital photo;
respectively dividing the first digital photo and third digital photo into r image data blocks, wherein r is an integer and each image data block contains a plurality of image data;
generating a second digital photo, wherein the second digital photo contains r image data blocks, and the r image data blocks of the second digital photo are generated according to the r image data blocks of the first digital photo and the r image data blocks of the third digital photo; and
displaying the second digital photo on the display device.

21. The digital photo album according to claim 20, wherein the image data of the image data blocks from the first one to the (i+1)-th one in the second digital photo are the same as the image data of the image data blocks from the first one to the (i+1)-th one in the third digital photo; if (2i+2−x) is greater than or equal to zero, the image data of the x-th image data block in the second digital photo are the same as the image data of a result obtained after performing an image processing function operation on the image data of the horizontally flipped (2i+3−x)-th image data block in the first digital photo and the image data of the x-th image data block in the first digital photo; if (2i+2−x) is less than zero, the image data of the x-th image data block in the second digital photo are the same as the image data of the x-th image data block in the first digital photo; wherein x is an integer from (i+2) to r, and i represents a number of displaying the second digital photo.

22. The digital photo album according to claim 21, wherein the image processing function sets the transparency of the image data of the horizontally flipped (2i+3−x)-th image data block in the first digital photo, and the image data of the x-th image data block in the second digital photo are obtained by adding the image data of the transparent horizontally flipped (2i+3−x)-th image data block in the first digital photo to the image data of the x-th image data block in the first digital photo.
